(19) United States
(12) Patent Application Publication
(10) Pub. No.: US 2023/0057050 A1
(43) Pub. Date: Feb. 23, 2023

(54) Uninterruptible Timed Electromagnetic Locking Mechanism

(71) Applicant: Jonathan Kauffman, New Market, MD (US)

(72) Inventor: Jonathan Kauffman, New Market, MD (US)

(21) Appl. No.: 17/408,402

(22) Filed: Aug. 21, 2021

(51) Int. Cl. E05B 43/00; H02M 7/04; H03K 19/20; E05B 47/00; E05B 65/52

(52) U.S. Cl. CPC E05B 43/005; H02M 7/04; H03K 19/20; E05B 47/0002; E05B 65/52; E05B 2047/0058

(57) ABSTRACT

The Uninterruptible Timed Electromagnetic Locking mechanism consists of a rechargeable DC battery pack wired in parallel downstream of the power supply, a logic circuit including a programmable timer relay which when activated by a switch, engages the lock for a user-set amount of time regardless of future switch states, and an electromagnetic lock controlled by the logic circuit and programmable timer relay.

### CROSS-REFERENCE TO RELATED APPLICATIONS

This patent proposal does not claim the benefit of any previously filed patent applications, be they provisional or nonprovisional.

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM LISTING COMPACT DISC APPENDIX

Not Applicable

### BACKGROUND OF THE INVENTION

This purpose of this invention is to provide the user with the means to make a storage container impenetrable during a set period of time (e.g. overnight). This invention has foreseeable applications as a diet aid, whether it is used to lock up food overnight, for intermittent fasting etc. While people trying to lose weight may hide their food in a cabinet overnight or even use a traditional lock on the cabinet for added security, it remains easy to access the hidden food if the user has a lapse in self-control by simply opening the cabinet or using a key. Even if a currently existing electronic lock is utilized, it can be disabled simply by cutting power to its input. This was the main problem which this invention aimed to solve: is there an electronic circuit, which when installed in a storage container, could render the storage container unopenable for a user-set time duration?

### BRIEF SUMMARY OF THE INVENTION

This Uninterruptible Timed Electromagnetic Locking Mechanism provides the means for a user to make a storage device impenetrable for a custom length of time. The electromagnetic lock provides a means of firmly holding a storage container's door closed. Due to the strength of the electromagnetic lock, it is almost impossible for a normal person to open the storage container when the lock is engaged. The power supply DC output for the lock is wired in parallel with a DC rechargeable battery pack which can be housed within a storage device. Even if the circuit is unplugged from power from an outlet, the lock will remain engaged until either the programmable timer relay opens, or the rechargeable DC power bank is drained. The entire circuit can be housed inside of a storage container, meaning that if the structural integrity of the container is not compromised, the circuit will continue to make the container unopenable. The timer relay is user-programmable, meaning the user can set the lock to engage for any reasonable amount of time (from 0.01 seconds to 9999 minutes).

### BRIEF DESCRIPTION OF DRAWING VIEWS

FIG. 1 shows an overall schematic of the uninterruptible timed electromagnetic locking mechanism.

FIG. 2 lists the bill of materials which is referenced in FIG. 1 for the uninterruptible timed electromagnetic locking mechanism.

FIG. 3 labels all the terminals on the programmable timer relay.

FIG. 4 depicts the power schematic for the uninterruptible timed electromagnetic locking mechanism. Wiring pertinent to the logic portion of the circuit is excluded in this figure for greater power detail clarity.

FIG. 5 shows the wiring connections pertinent to the logic portion of the circuit. A CD4011BE IC NAND chip is used for the logic of the circuit. Per the standard IC chip terminal numbering scheme, pin 1 is in the upper left corner of the chip, pin 7 in the bottom left, pin 8 in the bottom right, and pin 14 in the upper right. It should be noted that the wiring of the IC chip in FIG. 5 varies slightly from the wiring of the chip in FIG. 1, but the circuits are equivalent. Three two-input NAND gates are required for this circuit, but the CD4011BE has 4, so any three may be used provided they follow the logic in FIG. 6. Not depicted in this figure are the power connections (on pins 7&14) for the IC chip. See FIG. 4 for power connections. See FIG. 8 for the corresponding explicit IC pin connections.

FIG. 6 depicts the IC chip logic utilized in the uninterruptible timed electromagnetic locking mechanism. See FIG. 7 for more details including variable labels and a state table.

FIG. 7 provides a state table and details regarding the IC chip logic utilized in the uninterruptible timed electromagnetic locking mechanism.

FIG. 8 describes the IC pin connections. See FIG. 5 for the corresponding IC schematic.

### DETAILED DESCRIPTION OF THE INVENTION

### Power Connection Details:

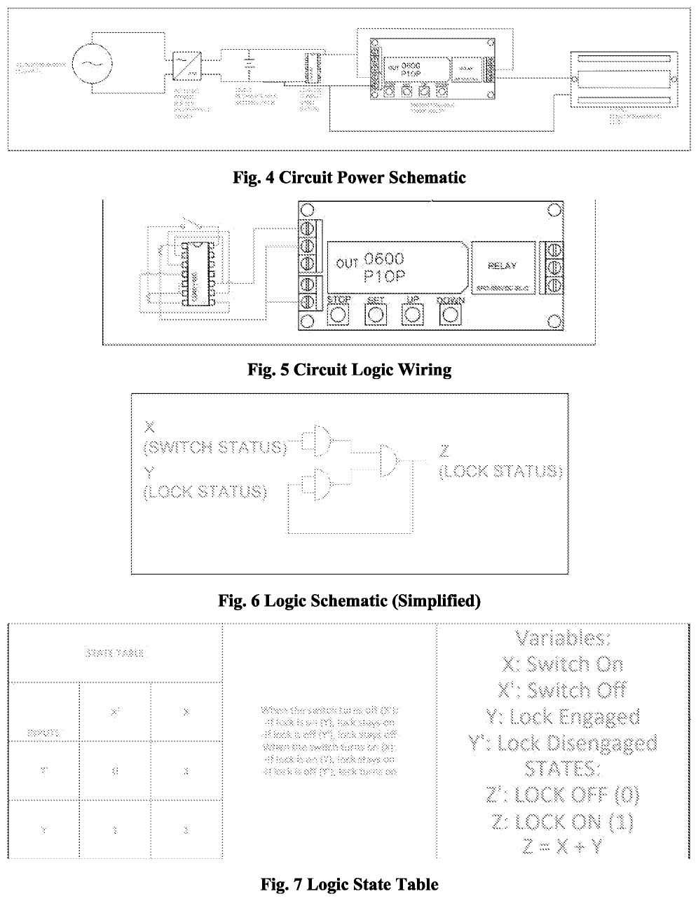

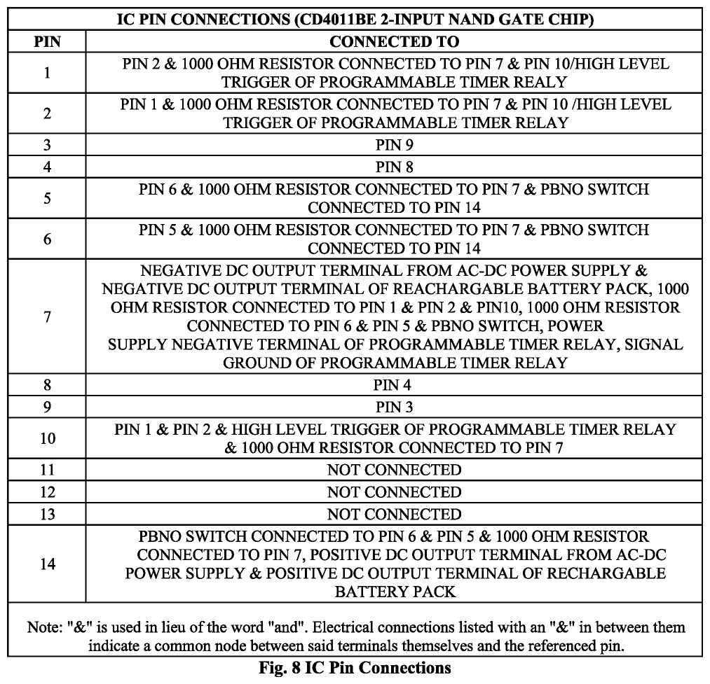

All wiring shall be 22AWG unless explicitly labeled otherwise. Reference FIG. 4 for the power connection schematic. Unless explicitly stated, see FIG. 4 for details supporting the explanation in this section.

The circuit is powered from a single phase, 120 VAC power source. The AC-DC power supply (see FIG. 2 for details) lowers the voltage from 120 VAC to 12 VDC to power the rest of the downstream circuit. A DC5521 1 Female to 2 Male splitter cable is used to wire the AC-DC power supply output in parallel with the 12 VDC rechargeable battery pack.

The positive 12 VDC node consisting of the positive lead of the DC output of the power supply and the positive lead connected to the rechargeable battery pack is then connected to Pin 14 of the CD4011BE IC chip, the power supply positive terminal of the programmable timer relay (see FIG. 3), and the common terminal on the relay of the programmable timer relay (see FIG. 3). The positive terminal of the 12 VDC electromagnetic lock is connected to the normally open relay output of the programmable timer relay (see FIG. 3) so that when the programmable timer relay is activated, 12 VDC flows through the relay, engaging the 12 VDC electromagnetic lock.

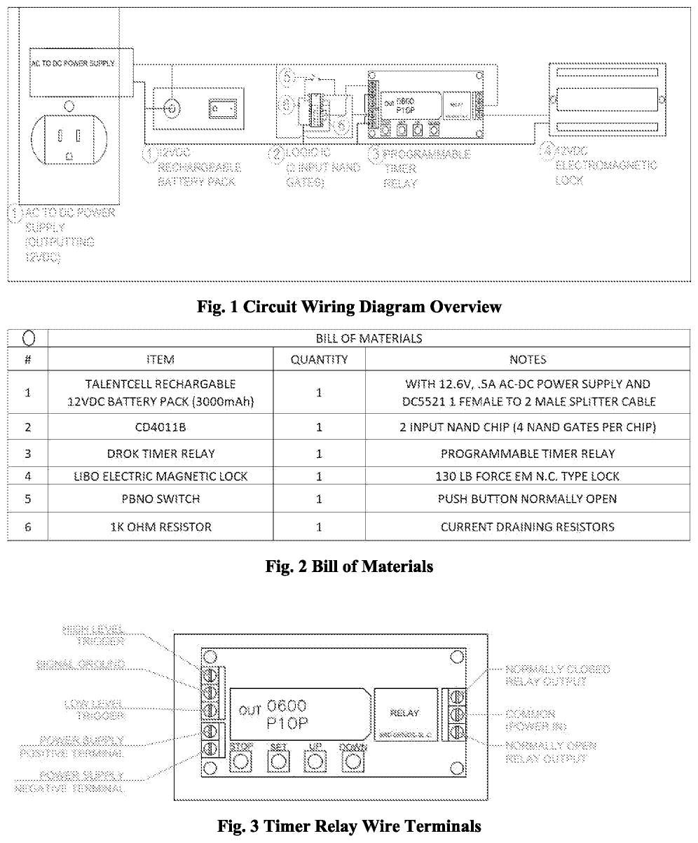

The common node (0 VDC) consisting of the negative lead of the DC output of the power supply and the negative lead connected to the rechargeable battery pack is connected to pin 7 of the CD4011BE IC chip, the power supply negative terminal of the programmable timer relay (see FIG. 3), the signal ground terminal of the programmable timer relay (see FIGS. 1 & 3), and the negative terminal of the 12 VDC electromagnetic lock.

### Logic System Details:

All wiring shall be 22AWG unless explicitly labeled otherwise. FIG. 6 depicts the logic schematic of the CD4011BE IC NAND chip. The logic circuit has two inputs: a PBNO switch used to activate the circuit (denoted as logic input X in FIGS. 6 & 7) and the current lock status (denoted as logic input Y in FIGS. 6 & 7). To make this locking system uninterruptible, the logic was designed such that once the circuit is activated (turning the PBNO switch on), the lock will be engaged until the timer relay opens after the user-set amount of time. Thus, the logic follows as per FIG. 7: when the switch turns off (X′), if the lock is on (Y), the lock stays on (Z) and if the lock is off (Y′), the lock stays off (Z′). When the switch turns on (X), if the lock is on (Y), the lock stays on (Z) and if the lock is off (Y′), the lock turns on (Z). Per FIG. 5, each logic circuit input has a 1000 ohm current draining resistor to prevent charge buildup which can facilitate incorrect input and output signals. The output signal (Z or Z′) from the CD4011BE IC chip is connected to the High-Level Trigger port of the programmable timer relay (See FIG. 3). The programmable timer relay shall operate in P1 mode, meaning that once the high level trigger signal is triggered, the relay closes for the set amount of time and then opens. Any additional trigger signals received at the high-level trigger port while the relay is closed are invalid and do not reset the timer.

### Miscellaneous Specifications and Details:

All wiring shall be 22AWG unless explicitly labeled otherwise. The programmable timer relay operates in P1 mode by default (as detailed in Logic System Details), so no mode configuration is required. To set the programmable timer relay run duration:
1. Hold down the SET button for at least three seconds.
2. Press SET again for a short duration to bypass the mode selection (the default P1 mode is used for this invention)
3. To change the timer's units, depress and release the STOP button. Repeat this until the desired time unit is selected (on the display, XXXX equates to seconds, XXX.X equates to centiseconds, XX.XX equates to milliseconds, and X.X.X.X equates to minutes, where X denotes an integer).
4. Once the timer units are selected, press the UP and DOWN buttons to adjust the numerical value on the display. This value will be how long the relay closes for when the circuit is activated.
5. Hold down the SET button for at least three seconds to exit the programming menu.

1. An uninterruptible timed electronic locking circuit comprising:
a. A circuit power source consisting of an AC-DC power supply whose output is wired in parallel with a rechargeable DC battery pack, and
b. A logic circuit consisting of a switch, NAND gates and a programmable timer relay connected immediately downstream of the circuit power source, and
c. An electromagnetic lock connected immediately downstream of the logic circuit,
Whereby the electromagnetic lock will engage and remain engaged when a user first turns on an input switch, regardless of future switch inputs, until the set time value of the user-programmable timer relay expires, and
Whereby the normal operation of the logic circuit and electromagnetic lock are not compromised by a loss of power at the input of the AC-DC power supply due to the rechargeable DC battery pack wired in parallel with the output of said AC-DC power supply.
